(19) United States
(12) Patent Application Publication
(10) Pub. No.: US 2022/0415994 A1
(43) Pub. Date: Dec. 29, 2022

(54) DISPLAY APPARATUS AND METHOD OF MANUFACTURING THE SAME

(71) Applicant: Samsung Display Co., Ltd., Yongin-si (KR)

(72) Inventors: Jungyun Jo, Yongin-si (KR); Subin Bae, Yongin-si (KR)

(21) Appl. No.: 17/699,141

(22) Filed: Mar. 20, 2022

(30) Foreign Application Priority Data
Jun. 24, 2021 (KR) 10-2021-0082337

(51) Int. Cl. H01L 27/32

(52) U.S. Cl. CPC H01L 27/3276; H01L 2227/323

(57) ABSTRACT

A display apparatus includes a first semiconductor layer, a first gate insulating layer, a first conductive layer, an etch stop layer, a second gate insulating layer, a second conductive layer, a first interlayer insulating layer, a second semiconductor layer, a third gate insulating layer, a second interlayer insulating layer, and a first connection electrode layer that are sequentially stacked. The first connection electrode layer includes a first connection electrode contacting the first semiconductor layer via a contact hole defined in the first gate insulating layer, the etch stop layer, the second gate insulating layer, the first interlayer insulating layer, the third gate insulating layer, and the second interlayer insulating layer.

### CROSS-REFERENCE TO RELATED APPLICATION

This application claims priority from and the benefit of Korean Patent Application No. 10-2021-0082337, filed on Jun. 24, 2021, which is hereby incorporated by reference for all purposes as if fully set forth herein.

### BACKGROUND

### Field

One or more embodiments relate to a display apparatus and a method of manufacturing the same, and more particularly, to a display apparatus capable of preventing or minimizing defects occurring in a manufacturing process, and a method of manufacturing the same.

### Discussion of the Background

In general, in a display apparatus such as an organic light-emitting display apparatus, thin-film transistors, connection electrodes, and wires are arranged in each (sub-)pixel in order to control luminance or the like of the (sub-)pixel. These thin-film transistors, connection electrodes, and wires form a multi-layered structure.

The above information disclosed in this Background section is only for understanding of the background of the inventive concepts, and, therefore, it may contain information that does not constitute prior art.

### SUMMARY

In display apparatuses of the related art, a defect may occur in the process of forming a contact hole to connect elements located on different layers.

In order to solve various problems including the problem as described above, one or more embodiments provide a display apparatus capable of preventing or minimizing defects occurring in a manufacturing process, and a method of manufacturing the same. However, the embodiments are examples, and do not limit the scope of the disclosure.

Devices constructed and methods performed according to the illustrative implementations of the invention are capable of preventing or minimizing defects in a device.

Additional features of the inventive concepts will be set forth in the description which follows, and in part will be apparent from the description, or may be learned by practice of the inventive concepts.

According to one or more embodiments, a display apparatus includes a substrate, a first semiconductor layer on the substrate, a first gate insulating layer covering the first semiconductor layer, a first conductive layer provided on the first gate insulating layer, the first conductive layer including a gate wire having a switching gate electrode, an etch stop layer that covers the first conductive layer, a second gate insulating layer that covers the etch stop layer, a second conductive layer provided on the second gate insulating layer, the second conductive layer including a upper capacitor electrode, a first interlayer insulating layer that covers the second conductive layer, a second semiconductor layer provided on the first interlayer insulating layer, a third gate insulating layer that covers the second semiconductor layer, a second interlayer insulating layer that covers the third gate insulating layer, and a first connection electrode layer provided on the second interlayer insulating layer, the first connection electrode layer including a first connection electrode in contact with the first semiconductor layer via a contact hole defined in the first gate insulating layer, the etch stop layer, the second gate insulating layer, the first interlayer insulating layer, the third gate insulating layer, and the second interlayer insulating layer.

The etch stop layer may include a material different from a material included in the first gate insulating layer, the second gate insulating layer, the first interlayer insulating layer, the third gate insulating layer, and the second interlayer insulating layer.

The etch stop layer may include an amorphous carbon layer, and each of the first gate insulating layer, the second gate insulating layer, the first interlayer insulating layer, the third gate insulating layer, and the second interlayer insulating layer may include an inorganic material.

Each of the first gate insulating layer, the second gate insulating layer, the first interlayer insulating layer, the third gate insulating layer, and the second interlayer insulating layer may include silicon oxide, silicon nitride, or silicon oxynitride.

The display apparatus may further include a first planarization layer that covers the first connection electrode layer, and a second connection electrode layer on the first planarization layer, the second connection electrode layer including a data wire connected to the first connection electrode via a contact hole defined in the first planarization layer.

The first planarization layer may include an organic insulating layer.

The first connection electrode layer may further include a second connection electrode in contact with the first semiconductor layer via a first contact hole defined in the first gate insulating layer, the etch stop layer, the second gate insulating layer, the first interlayer insulating layer, the third gate insulating layer, and the second interlayer insulating layer.

The second connection electrode layer may further include a driving voltage wire connected to the second connection electrode via a contact hole defined in the first planarization layer.

The second connection electrode may be connected to the upper capacitor electrode via a second contact hole defined in the first interlayer insulating layer, the third gate insulating layer, and the second interlayer insulating layer.

The first connection electrode layer may further include a third connection electrode in contact with the first semiconductor layer via a contact hole defined in the first gate insulating layer, the etch stop layer, the second gate insulating layer, the first interlayer insulating layer, the third gate insulating layer, and the second interlayer insulating layer.

The second connection electrode layer may further include an upper connection electrode connected to the third connection electrode via a contact hole defined in the first planarization layer.

The display apparatus may further include a second planarization layer covering the second connection electrode layer, and a pixel electrode connected to the upper connection electrode through a contact hole defined in the second planarization layer.

According to one or more embodiments, a method of manufacturing a display apparatus includes forming a first semiconductor layer on a substrate, forming a first gate insulating layer to cover the first semiconductor layer, forming, on the first gate insulating layer, a first conductive layer including a gate wire including a switching gate electrode, forming an etch stop layer to cover the first conductive layer, forming a second gate insulating layer to cover the etch stop layer, forming, on the second conductive layer, a second conductive layer including an upper capacitor electrode, forming a first interlayer insulating layer to cover the second conductive layer, forming a second semiconductor layer on the first interlayer insulating layer, forming a third gate insulating layer to cover the second semiconductor layer, forming a second interlayer insulating layer to cover the third gate insulating layer, forming a first temporary contact hole in the second gate insulating layer, the first interlayer insulating layer, the third gate insulating layer, and the second interlayer insulating layer, forming a second temporary contact hole by removing a portion of the etch stop layer exposed by the first temporary contact hole, forming a contact hole in the first gate insulating layer, the etch stop layer, the second gate insulating layer, the first interlayer insulating layer, the third gate insulating layer, and the second interlayer insulating layer by removing a portion of the first gate insulating layer exposed by the second temporary contact hole, and forming, on the second interlayer insulating layer, a first connection electrode layer including a first connection electrode in contact with the first semiconductor layer via the contact hole.

The forming of the first temporary contact hole may include using a gas including fluorine, and the forming of the second temporary contact hole may include oxygen plasma treatment.

The removing of the portion of the first gate insulating layer exposed by the second temporary contact hole may include using a gas including fluorine.

A material used in the forming of the etch stop layer is different from a material used in the forming of the first gate insulating layer, the forming of the second gate insulating layer, the forming of the first interlayer insulating layer, the forming of the third gate insulating layer, and the forming of the second interlayer insulating layer.

The forming of the etch stop layer may include forming an amorphous carbon layer, and each of the forming of the first gate insulating layer, the forming of the second gate insulating layer, the forming of the first interlayer insulating layer, the forming of the third gate insulating layer, and the forming of the second interlayer insulating layer may include forming an inorganic insulating layer.

Each of the forming of the first gate insulating layer, the forming of the second gate insulating layer, the forming of the first interlayer insulating layer, the forming of the third gate insulating layer, and the forming of the second interlayer insulating layer may include forming a layer including silicon oxide, silicon nitride or silicon oxynitride.

The method may further include forming a first planarization layer to cover the first connection electrode layer, forming, on the first planarization layer, a contact hole exposing at least a portion of the first connection electrode, and forming, on the first planarization layer, a second connection electrode layer including a data wire connected to the first connection electrode via the contact hole defined in the first planarization layer.

The forming of the first planarization layer may include forming an organic insulating layer.

It is to be understood that both the foregoing general description and the following detailed description are illustrative and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate illustrative embodiments of the invention, and together with the description serve to explain the inventive concepts.

The above and other aspects, features, and advantages of certain embodiments of the disclosure will be more apparent from the following description taken in conjunction with the accompanying drawings, in which:

FIG. 1 is a schematic plan view of a portion of a display apparatus according to an embodiment that is constructed according to principles of the invention.

FIG. 2 is a schematic side view of the display apparatus of FIG. 1.

FIG. 3 is an equivalent circuit diagram of a pixel included in the display apparatus of FIG. 1.

FIG. 4 is a schematic layout diagram of locations of transistors and capacitors in pixels included in the display apparatus of FIG. 1.

FIGS. 5, 6, 7, 8, 9, 10, and 11 are schematic layout diagrams of elements such as transistors and capacitors for each layer in the display apparatus illustrated in FIG. 4.

FIG. 12 is a schematic cross-sectional view of the display apparatus illustrated in FIG. 4 taken along lines I-I′, II-II′, and III-III′.

FIGS. 13, 14, 15, and 16 are schematic cross-sectional views illustrating operations in a method of manufacturing the display apparatus of FIG. 1.

FIG. 17 is a schematic cross-sectional view of cross-sections of portions of a display apparatus according to an embodiment.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the x-axis, the y-axis, and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

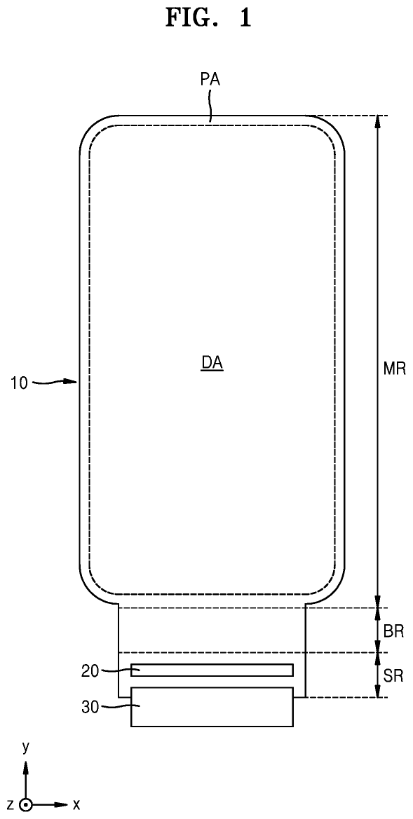

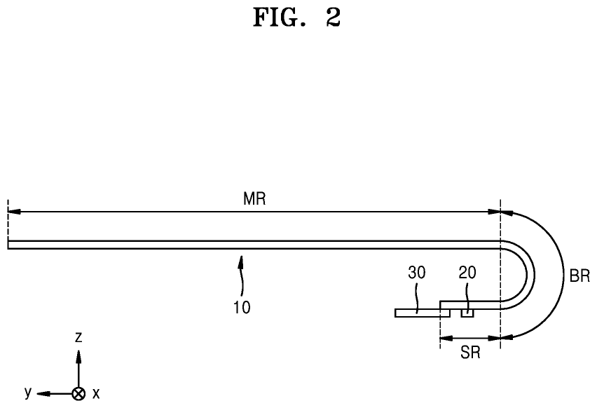

FIG. 1 is a schematic plan view of a portion of a display apparatus according to an embodiment that is constructed according to principles of the invention, and FIG. 2 is a schematic side view of the display apparatus of FIG. 1. The display apparatus according to the embodiment is partially bent as illustrated in FIG. 2, but is illustrated as not bent in FIG. 1 for convenience of description.

As illustrated in FIGS. 1 and 2, the display apparatus according to the embodiment includes a display panel 10. Any type of display apparatus may be used, provided that the display apparatus includes the display panel 10. For example, the display apparatus may be various products such as a smartphone, a tablet, a laptop computer, a television, a billboard, etc.

The display panel 10 includes a display area DA and a peripheral area PA outside the display area DA. The display area DA displays images, and a plurality of pixels may be arranged in the display area DA. When seen from a direction perpendicular to the display panel 10, the display area DA may have various shapes, for example, a circular shape, an elliptical shape, a polygonal shape, a certain figure shape, etc. In FIG. 1, it is illustrated that the display area DA has a rectangular shape having round corners.

The peripheral area PA may be arranged outside the display area DA. A width of a portion of the peripheral area PA (in an x-axis direction) may be less than a width of the display area DA (in the x-axis direction). Through the aforedescribed structure, at least a portion of the peripheral area PA may be easily bent, as described below.

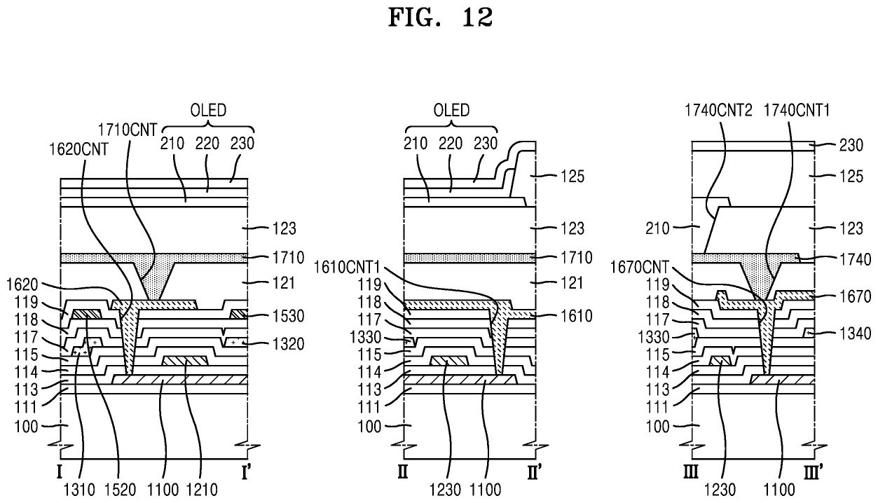

Because the display panel 10 includes a substrate 100 (see FIG. 12), it may be appreciated that the substrate 100 includes the display area DA and the peripheral area PA as described above. Hereinafter, it will be described that the substrate 100 includes the display area DA and the peripheral area PA for convenience of description.

The display panel 10 may also include a main region MR, a bending region BR outside the main region MR, and a sub-region SR opposite to the main region MR based on the bending region BR. As illustrated in FIG. 2, the display panel 10 is bent at the bending region BR, and thus, the sub-region SR may at least partially overlap the main region MR when seen from a z-axis direction. One or more embodiments are not limited to a bendable display apparatus, but may be also applied to a display apparatus that is not bendable. The sub-region SR may be a non-display area, as described below. Because the display panel 10 is bent at the bending region BR, the non-display area is not visible or may be visible such that a visible area of the non-display area is reduced when the display apparatus is seen from the front (in a −z direction).

A driving chip 20 may be in the sub-region SR of the display panel 10. The driving chip 20 may include an integrated circuit for driving the display panel 10. The integrated circuit may be a data driving integrated circuit for generating a data signal, but one or more embodiments are not limited thereto.

The driving chip 20 may be mounted on the sub-region SR of the display panel 10. Although the driving chip 20 is mounted on the same surface as a display surface of the display area DA, the driving chip 20 may be on a rear surface of the main region MR when the display panel 10 is bent at the bending region BR as described above.

A printed circuit board 30 or the like may be attached to an end portion of the sub-region SR of the display panel 10. The printed circuit board 30 or the like may be electrically connected to the driving chip 20 or the like via a pad on the substrate.

Hereinafter, a display apparatus according to an embodiment is described as an organic light-emitting display apparatus as an example, but the display apparatus is not limited thereto. In another embodiment, the display apparatus according to the embodiment may include an inorganic light-emitting display, an inorganic electroluminescence (EL) display apparatus, or a quantum dot light-emitting display apparatus. For example, an emission layer of a display element included in the display apparatus may include an organic material or an inorganic material. Also, the display apparatus may include an emission layer, and quantum dot layer on a path of light emitted from the emission layer.

As described above, the display panel 10 includes the substrate 100. Various elements included in the display panel 10 may be on the substrate 100. The substrate 100 may include glass, metal, or a polymer resin. When the display panel 10 is bent at the bending region BR as described above, the substrate 100 needs to be flexible or bendable. In this case, the substrate 100 may include, for example, a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may be variously modified, for example, the substrate 100 may have a multi-layered structure including two layers each having a polymer resin and a barrier layer including an inorganic material such as silicon oxide, silicon nitride, silicon oxynitride, etc., between the two layers.

A plurality of pixels are arranged in the display area DA. Each of the pixels denotes a sub-pixel and may include a display element such as an organic light-emitting diode (OLED). Each of the pixels may emit, for example, red light, green light, blue light, or white light.

Each of the pixels may be electrically connected to external circuits in the peripheral area PA. A scan driving circuit, an emission control driving circuit, a terminal, a driving power supply line, an electrode power supply line, and the like may be in the peripheral area PA. The scan driving circuit may be configured to provide a scan signal to the pixel via a scan line. The emission control driving circuit may be configured to provide an emission control signal to the pixel via an emission control line. The terminal in the peripheral area PA of the substrate 100 may be exposed without being covered by an insulating layer to be electrically connected to the printed circuit board 30. A terminal of the printed circuit board 30 may be electrically connected to a terminal of the display panel 10.

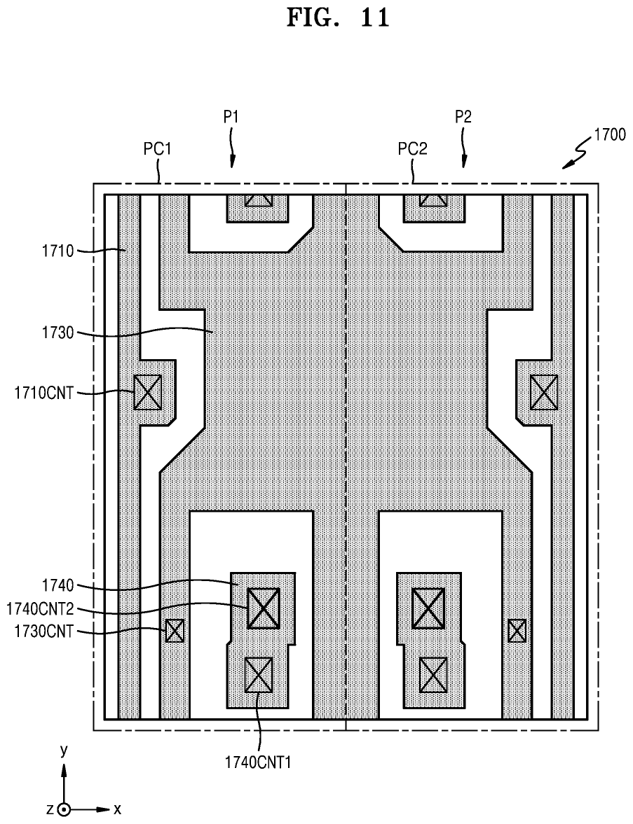

The printed circuit board 30 is configured to transmit a signal or power from a controller to the display panel 10. A control signal generated by the controller may be respectively transmitted to the driving circuits via the printed circuit board 30. Also, the controller may transmit a first power voltage ELVDD to the driving power supply line and may provide a second power voltage ELVSS to the electrode power supply line. The first power voltage ELVDD (or a driving voltage) may be transmitted to each pixel via a driving voltage wire 1730 (see FIG. 11) connected to the driving power supply line, and the second power voltage ELVSS (or a common voltage) may be transmitted to an opposite electrode 230 (see FIG. 12) of the pixel connected to the electrode power supply line. The electrode power supply line has a loop shape having an open side and may partially surround the display area DA.

Moreover, the controller may generate a data signal, and the generated data signal may be transmitted to the pixel via the driving chip 20 and a data wire 1710 (see FIG. 11).

For reference, the term “line” may denote “wiring.” This will be also applied to embodiments and modifications thereof that will be described later.

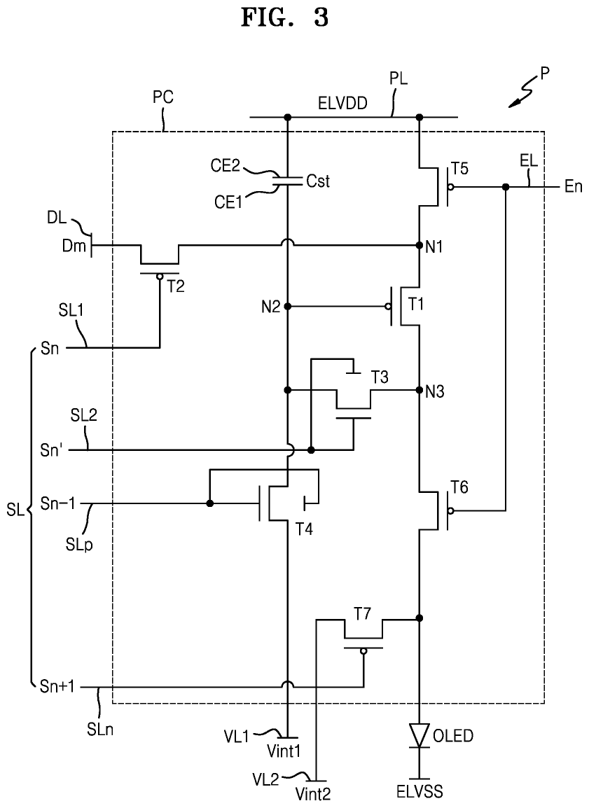

FIG. 3 is an equivalent circuit diagram of a pixel P included in the display apparatus of FIG. 1. As illustrated in FIG. 3, the pixel P includes a pixel circuit PC and an organic light-emitting diode OLED electrically connected to the pixel circuit PC.

The pixel circuit PC, as illustrated in FIG. 3, may include a plurality of thin-film transistors T1, T2, T3, T4, T5, T6, and T7, and a storage capacitor Cst. The thin-film transistors T1 to T7 and the storage capacitor Cst may be connected to signal lines SL1, SL2, SLp, SLn, EL, and DL, a first initialization voltage line VL1, a second initialization voltage line VL2, and a driving voltage line PL. At least one of the lines, for example, the driving voltage line PL, may be shared by neighboring pixels P.

The thin-film transistors T1 to T7 may include a driving transistor T1, a switching transistor T2, a compensation transistor T3, a first initialization transistor T4, an operation control transistor T5, an emission control transistor T6, and a second initialization transistor T7.

The organic light-emitting diode OLED may include a first electrode (e.g., pixel electrode) and a second electrode (e.g., opposite electrode), and the first electrode of the organic light-emitting diode OLED is connected to the driving transistor T1 via the emission control transistor T6 to receive a driving current, and the second electrode may be configured to receive a second power voltage ELVSS. The organic light-emitting diode OLED may be configured to generate light of a luminance corresponding to the driving current.

Some of the thin-film transistors T1 to T7 may each be an n-channel metal-oxide semiconductor field effect transistor (MOSFET) (NMOS), and the others thereof may each be a p-channel MOSFET (PMOS). For example, from among the thin-film transistors T1 to T7, the compensation transistor T3 and the first initialization transistor T4 may each be an NMOS transistor, and the others may each be a PMOS transistor. Alternatively, from among the thin-film transistors T1 to T7, the compensation transistor T3, the first initialization transistor T4, and the second initialization transistor T7 may each be an NMOS transistor, and the others may each be a PMOS transistor. Alternatively, the thin-film transistors T1 to T7 may be all NMOS or PMOS transistors. The thin-film transistors T1 to T7 may include amorphous silicon or polysilicon. As necessary, a thin-film transistor that is an NMOS transistor may include an oxide semiconductor. Hereinafter, a case in which the compensation transistor T3 and the first initialization transistor T4 are NMOS transistors each including an oxide semiconductor, and the others thereof are PMOS transistors will be described for convenience of description.

The signal lines may include a first scan line SL1 configured to transmit a first scan signal Sn, a second scan line SL2 configured to transmit a second scan signal Sn′, a previous scan line SLp configured to transmit a previous scan signal Sn−1 to the first initialization transistor T4, a next scan line SLn configured to transmit a next scan signal Sn+1 to the second initialization transistor T7, an emission control line EL configured to transmit an emission control signal En to the operation control transistor T5 and the emission control transistor T6, and a data line DL configured to transmit a data signal Dm while intersecting the first scan line SL1.

The driving voltage line PL is configured to transmit a driving voltage ELVDD to the driving transistor T1, the first initialization voltage line VL1 is configured to transmit a first initialization voltage Vint1 for initializing the driving transistor T1, and the second initialization voltage line VL2 may be configured to transmit a second initialization voltage Vint2 for initializing the first electrode of the organic light-emitting diode OLED.

A driving gate electrode of the driving transistor T1 may be connected to the storage capacitor Cst via a second node N2, one of a source region and a drain region of the driving transistor T1 may be connected to the driving voltage line PL after passing through the operation control transistor T5 via a first node N1, and the other of the source region and the drain region of the driving transistor T1 may be electrically connected to the first electrode (pixel electrode) of the organic light-emitting diode OLED after passing through the emission control transistor T6 via a third node N3. The driving transistor T1 is configured to receive the data signal Dm according to a switching operation of the switching transistor T2 to supply the driving current to the organic light-emitting diode OLED. That is, the driving transistor T1 may be configured to control an amount of current flowing from the first node N1 that is electrically connected to the driving voltage line PL to the organic light-emitting diode OLED, in response to a voltage applied to the second node N2, the voltage varying due to the data signal Dm.

A switching gate electrode of the switching transistor T2 may be connected to the first scan line SL1 configured to transmit the first scan signal Sn, one of a source region and a drain region of the switching transistor T2 may be connected to the data line DL, and the other of the source region and the drain region of the switching transistor T2 may be connected to the driving transistor T1 via the first node N1 and then may be connected to the driving voltage line PL via the operation control transistor T5. The switching transistor T2 may be configured to transmit the data signal Dm from the data line DL to the first node N1, in response to the voltage applied to the first scan line SL1. That is, the switching transistor T2 is turned on in response to the first scan signal Sn received via the first scan line SL1 and may perform a switching operation for transmitting the data signal Dm transmitted via the data line DL to the driving transistor T1 via the first node N1.

A compensation gate electrode of the compensation transistor T3 is connected to the second scan line SL2. One of a source region and a drain region of the compensation transistor T3 may be connected to the first electrode of the organic light-emitting diode OLED after passing through the emission control transistor T6 via the third node N3. The other of the source region and the drain region of the compensation transistor T3 may be connected to a first capacitor electrode CE1 of the storage capacitor Cst and the driving gate electrode of the driving transistor T1 via the second node N2. The compensation transistor T3 may be turned on in response to the second scan signal Sn′ received via the second scan line SL2 to cause the driving transistor T1 to be diode-connected.

A first initialization gate electrode of the first initialization transistor T4 may be connected to the previous scan line SLp. One of a source region and a drain region of the first initialization transistor T4 may be connected to the first initialization voltage line VL1. The other of the source region and the drain region of the first initialization transistor T4 may be connected to the first capacitor electrode CE1 of the storage capacitor Cst and the driving gate electrode of the driving transistor T1 via the second node N2. The first initialization transistor T4 may be configured to apply the first initialization voltage Vint1 from the first initialization voltage line VL1 to the second node N2, in response to the voltage applied to the previous scan line SLp. That is, the first initialization transistor T4 is turned on in response to the previous scan signal Sn−1 transmitted via the previous scan line SLp and may be configured to transmit the first initialization voltage Vint1 to the driving gate electrode of the driving transistor T1 and perform an initialization operation for initializing a voltage at the driving gate electrode of the driving transistor T1.

An operation control gate electrode of the operation control transistor T5 may be connected to the emission control line EL, one of the source region and the drain region of the operation control transistor T5 may be connected to the driving voltage line PL, and the other thereof may be connected to the driving transistor T1 and the switching transistor T2 via the first node Ni.

An emission control gate electrode of the emission control transistor T6 may be connected to the emission control line EL, one of a source region and a drain region of the emission control transistor T6 may be connected to the driving transistor T1 and the compensation transistor T3 via the third node N3, and the other of the source region and the drain region of the emission control transistor T6 may be electrically connected to the first electrode (pixel electrode) of the organic light-emitting diode OLED.

The operation control transistor T5 and the emission control transistor T6 are simultaneously turned on in response to the emission control signal En transmitted via the emission control line EL to transmit the driving voltage ELVDD to the organic light-emitting diode OLED and to allow the driving current to flow in the organic light-emitting diode OLED.

A second initialization gate electrode of the second initialization transistor T7 may be connected to the next scan line SLn, one of a source region and a drain region of the second initialization transistor T7 may be connected to the first electrode (pixel electrode) of the organic light-emitting diode OLED, and the other of the source region and the drain region of the second initialization transistor T7 may be connected to the second initialization voltage line VL2 to receive the second initialization voltage Vint2. The second initialization transistor T7 is turned on in response to the next scan signal Sn+1 transmitted via the next scan line SLn and is configured to initialize the first electrode (pixel electrode) of the organic light-emitting diode OLED. The next scan line SLn may be the same as the first scan line SL1. In this case, the corresponding scan line is configured to transmit the same electrical signal with a time difference, so as to function as the first scan line SL1 or the next scan line SLn. That is, the next scan line SLn may be a first scan line of a pixel that is adjacent to the pixel P illustrated in FIG. 3 and is electrically connected to the data line DL.

The second initialization transistor T7 may be connected to the first scan line SL1 as illustrated in FIG. 3. However, one or more embodiments are not limited thereto, that is, the second initialization transistor T7 may be connected to the emission control line EL and may be driven in response to the emission control signal En.

The storage capacitor Cst may include the first capacitor electrode CE1 and a second capacitor electrode CE2. The first capacitor electrode CE1 of the storage capacitor Cst is connected to the driving gate electrode of the driving transistor T1 via the second node N2, and the second capacitor electrode CE2 of the storage capacitor Cst is connected to the driving voltage line PL. The storage capacitor Cst may be configured to store a charge corresponding to a difference between the voltage at the driving gate electrode of the driving transistor T1 and the driving voltage ELVDD.

Detailed operations of each pixel P according to the embodiment are as follows.

During an initialization period, when the previous scan signal Sn−1 is supplied via the previous scan line SLp, the first initialization transistor T4 is turned on in response to the previous scan signal Sn−1, and the driving transistor T1 is initialized in response to the first initialization voltage Vint1 supplied from the first initialization voltage line VL1.

During a data programming period, when the first scan signal Sn and the second scan signal Sn′ are supplied via the first scan line SL1 and the second scan line SL2, the switching transistor T2 and the compensation transistor T3 are turned on in response to the first scan signal Sn and the second scan signal Sn′. In this case, the driving transistor T1 is diode-connected by the compensation transistor T3 that is turned on, and is biased in a forward direction. Then, a compensation voltage (Dm+Vth, Vth has a negative value) that is obtained by subtracting a threshold voltage (Vth) of the driving transistor T1 from the data signal Dm supplied from the data line DL is applied to the driving gate electrode of the driving transistor T1. The driving voltage ELVDD and the compensation voltage (Dm+Vth) are applied to opposite ends of the storage capacitor Cst, and a charge corresponding to a difference between the voltages at opposite ends thereof is stored in the storage capacitor Cst.

During an emission period, the operation control transistor T5 and the emission control transistor T6 are turned on in response to the emission control signal En supplied from the emission control line EL. The driving current is generated according to a difference between the voltage at the driving gate electrode of the driving transistor T1 and the driving voltage ELVDD, and the driving current is supplied to the organic light-emitting diode OLED via the emission control transistor T6.

As described above, some of the thin-film transistors T1 to T7 may each include an oxide semiconductor. For example, the compensation transistor T3 and the first initialization transistor T4 may each include an oxide semiconductor.

Because polysilicon has high reliability, a precisely intended current may be controlled to flow. Therefore, the driving transistor T1 that directly affects the brightness of the display apparatus includes a semiconductor layer including the polysilicon having high reliability, and thus, the display apparatus of high resolution may be implemented. In addition, the oxide semiconductor has a high carrier mobility and a low leakage current, a voltage drop is not great despite a long driving time. That is, even during low-frequency driving, a color change in the image due to the voltage drop is not great, low-frequency driving of the oxide semiconductor is possible. Therefore, the compensation transistor T3 and the first initialization transistor T4 each include the oxide semiconductor, and thus, the generation of a leakage current may be prevented, and the display apparatus having reduced power consumption may be implemented.

Moreover, because the oxide semiconductor is sensitive for light, there may be a variation in a current amount due to external light. Therefore, a metal layer may be under the oxide semiconductor in order to absorb or reflect the external light. Accordingly, as illustrated in FIG. 3, the compensation transistor T3 and the first initialization transistor T4 including the oxide semiconductor may each have gate electrodes on and under the oxide semiconductor layer. That is, when seen from a direction perpendicular to the upper surface of the substrate 100 (the z-axis direction), the metal layer under the oxide semiconductor may overlap the oxide semiconductor.

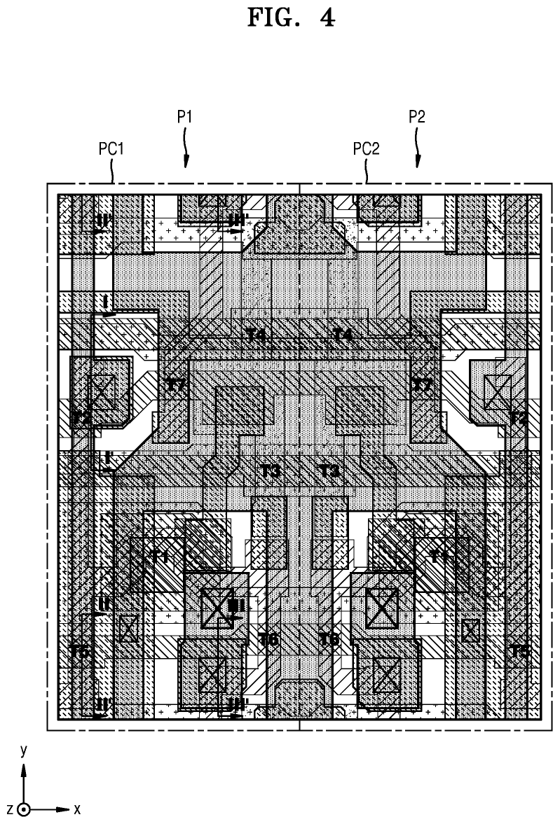

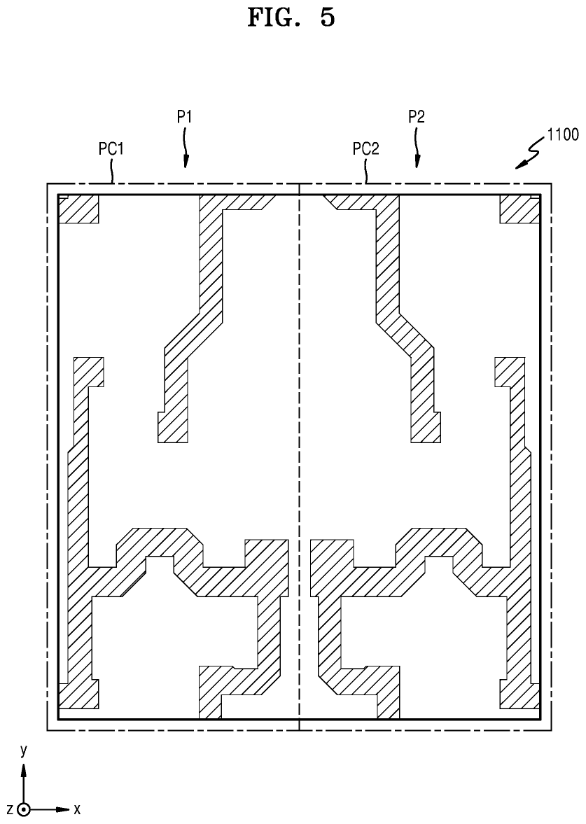

FIG. 4 is a schematic layout diagram of locations of the thin-film transistors T1 to T7 and the storage capacitor Cst in pixels included in the display apparatus of FIG. 1, FIGS. 5 to 11 are schematic layout diagrams of elements such as the thin-film transistors T1 to T7 and the storage capacitor Cst for each layer in the display apparatus illustrated in FIG. 4, and FIG. 12 is a schematic cross-sectional view of the display apparatus illustrated in FIG. 4 taken along lines I-I′, and

As illustrated in the drawings, the display apparatus includes a first pixel P1 and a second pixel P2 adjacent to each other. The first pixel P1 and the second pixel P2 may be symmetrical with each other based on a virtual line as illustrated in FIG. 4 or the like. Otherwise, the first pixel P1 and the second pixel P2 may have the same structure rather than a symmetrical structure. The first pixel P1 includes a first pixel circuit PC1 and the second pixel P2 includes a second pixel circuit PC2. Hereinafter, some conductive patterns will be described based on the first pixel circuit PC1 for convenience of description, but the conductive patterns may also be symmetrically provided in the second pixel circuit PC2.

A buffer layer 111 (see FIG. 12) including silicon oxide, silicon nitride, or silicon oxynitride may be on the substrate 100. The buffer layer 111 may prevent metal atoms or impurities from dispersing from the substrate 100 to a first semiconductor layer 1100 thereon. Also, the buffer layer 111 may adjust a speed of providing heat during a crystallization process for forming the first semiconductor layer 1100, so that the first semiconductor layer 1100 may be evenly crystallized.

The first semiconductor layer 1100 as illustrated in FIG. 5 may be on the buffer layer 111. The first semiconductor layer 1100 may include a silicon semiconductor. For example, the first semiconductor layer 1100 may include amorphous silicon or polysilicon. In detail, the first semiconductor layer 1100 may include polysilicon that is crystallized at a low temperature. As necessary, ions may be implanted into at least a portion of the first semiconductor layer 1100.

Because the driving transistor T1, the switching transistor T2, the operation control transistor T5, the emission control transistor T6, and the second initialization transistor T7 may each be a PMOS transistor as described above, the above thin-film transistors may be provided along the first semiconductor layer 1100 as illustrated in FIG. 5.

A first gate insulating layer 113 (see FIG. 12) covers the first semiconductor layer 1100 and may be on the substrate 100. The first gate insulating layer 113 may include an insulating material. For example, the first gate insulating layer 113 may include an inorganic insulating layer such as silicon oxide, silicon nitride, silicon oxynitride, aluminum oxide, etc.

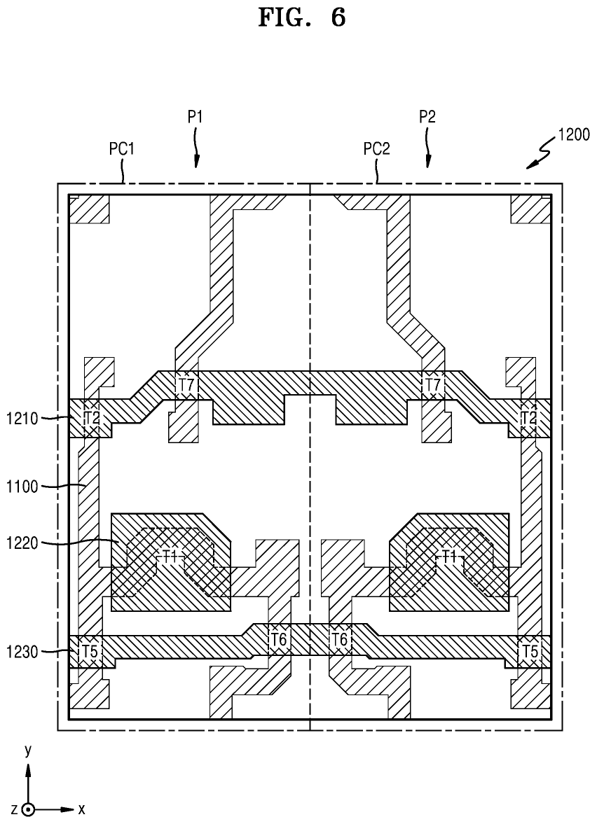

A first conductive layer 1200 as illustrated in FIG. 6 may be on the first gate insulating layer 113. In FIG. 6, the first conductive layer 1200 is illustrated along with the first semiconductor layer 1100 for convenience. The first conductive layer 1200 may include a first gate wire 1210, a first gate electrode 1220, and a second gate wire 1230. The first conductive layer 1200 may be referred to as the first gate layer.

The first gate wire 1210 may extend in a first direction (the x-axis direction). The first gate wire 1210 may be the first scan line SL1 or the next scan line SLn illustrated in FIG. 3. That is, in the first pixel P1 as illustrated in FIG. 6, the first gate wire 1210 corresponds to the first scan line SL1 of FIG. 3, and in a pixel adjacent to the first pixel P1 (in a +y direction), the first gate wire 1210 may correspond to the next scan line SLn of FIG. 3. Accordingly, the first scan signal Sn and the next scan signal Sn+1 may be applied to the pixels via the first gate wire 1210. In the first gate wire 1210, portions overlapping the first semiconductor layer 1100 may include the switching gate electrode of the switching transistor T2 and the second initialization gate electrode of the second initialization transistor T7.

The first gate electrode 1220 may have an isolated shape. The first gate electrode 1220 may be the driving gate electrode of the driving transistor T1. In the first semiconductor layer 1100, a portion overlapping the first gate electrode 1220 and a peripheral portion may be referred to as a driving semiconductor layer.

The second gate wire 1230 may extend in the first direction (the x-axis direction). The second gate wire 1230 may correspond to the emission control line EL of FIG. 3. In the second gate wire 1230, portions overlapping the first semiconductor layer 1100 may include the operation control gate electrode of the operation control transistor T5 and the emission control gate electrode of the emission control transistor T6. The emission control signal En may be applied to the pixels via the second gate wire 1230.

The first conductive layer 1200 may include a metal, an alloy, conductive metal oxide, a transparent conductive material, etc. For example, the first conductive layer 1200 may include silver (Ag), an alloy including silver, molybdenum (Mo), an alloy including molybdenum, aluminum (Al), an alloy include aluminum, aluminum nitride (AlN), tungsten (W), tungsten nitride (WN), copper (Cu), nickel (Ni), chrome (Cr), chrome nitride (CrN), titanium (Ti), tantalum (Ta), platinum (Pt), scandium (Sc), indium tin oxide (ITO), indium zinc oxide (IZO), etc. The first conductive layer 1200 may have a multi-layered structure, for example, a dual-layered structure including Mo/A1 or a triple-layered structure including Mo/Al/Mo.

An etch stop layer 114 (see FIG. 12) covers the first conductive layer 1200 and may be on the first gate insulating layer 113. The etch stop layer 114 may include a material different from the material included in the first gate insulating layer 113. In detail, the etch stop layer 114 may include an amorphous carbon layer. When the etch stop layer 114 is the amorphous carbon layer, the etch stop layer 114 may also be formed by using a CVD apparatus, as in a case where the first gate insulating layer 113, which is an inorganic insulating layer such as silicon oxide, silicon nitride, silicon oxynitride, or aluminum oxide, is formed by using a CVD apparatus. That is, the process of forming the first gate insulating layer 113 and the like and the process of forming the etch stop layer 114 differ only in gases used, and substantially the same or similar equipment is used. Therefore, the process of manufacturing the display apparatus may not be complicated.

A second gate insulating layer 115 (see FIG. 12) may be on the etch stop layer 114. The second gate insulating layer 115 may include an insulating material that is the same as or similar to that of the first gate insulating layer 113.

A second conductive layer 1300 may be on the second gate insulating layer 115. The second conductive layer 1300 may include a third gate wire 1310, a fourth gate wire 1320, an upper capacitor electrode 1330, and a first initialization voltage wire 1340 (that is, the first initialization voltage line VL1 of FIG. 3).

The third gate wire 1310 may extend in the first direction (the x-axis direction). The third gate wire 1310 may correspond to the previous scan line SLp of FIG. 3. When seen from a direction perpendicular to the substrate 100 (z-axis direction), the third gate wire 1310 may be spaced apart from the first gate wire 1210. The previous scan signal Sn−1 may be applied to the pixels via the third gate wire 1310. In the third gate wire 1310, a portion overlapping a second semiconductor layer 1400 that will be described below may include a first initialization lower gate electrode of the first initialization transistor T4.

The fourth gate wire 1320 may extend in the first direction (the x-axis direction). The fourth gate wire 1320 may correspond to the second scan line SL2 of FIG. 3. When seen in the direction perpendicular to the substrate 100 (the z-axis direction), the fourth gate wire 1320 may be spaced apart from the first gate wire 1210 and the third gate wire 1310. The second scan signal Sn′ may be applied to the pixels via the fourth gate wire 1320. In the fourth gate wire 1320, a portion overlapping the second semiconductor layer 1400 that will be described below may include a compensation lower gate electrode of the compensation transistor T3.

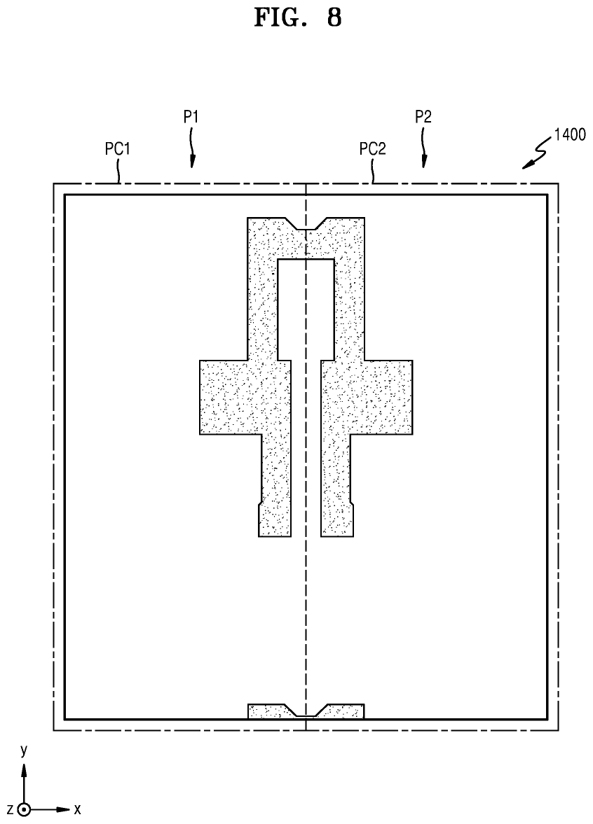

The third gate wire 1310 and the fourth gate wire 1320 are under the second semiconductor layer 1400 that will be described below with reference to FIG. 8, and may function as lower protective metals for protecting portions of the second semiconductor layer 1400, which overlap the third gate wire 1310 and the fourth gate wire 1320, as well as the gate electrodes.

The upper capacitor electrode 1330 may overlap the first gate electrode 1220 and extend in the first direction (the x-axis direction). The upper capacitor electrode 1330 corresponds to the second capacitor electrode CE2 of FIG. 3 and may constitute the storage capacitor Cst along with the first gate electrode 1220. That is, the first gate electrode 1220 may be a lower capacitor electrode corresponding to the first capacitor electrode CE1 of FIG. 3. The driving voltage ELVDD may be applied to the upper capacitor electrode 1330. Also, the upper capacitor electrode 1330 may include a hole passing therethrough, and at least a portion of the first gate electrode 1220 may overlap the hole.

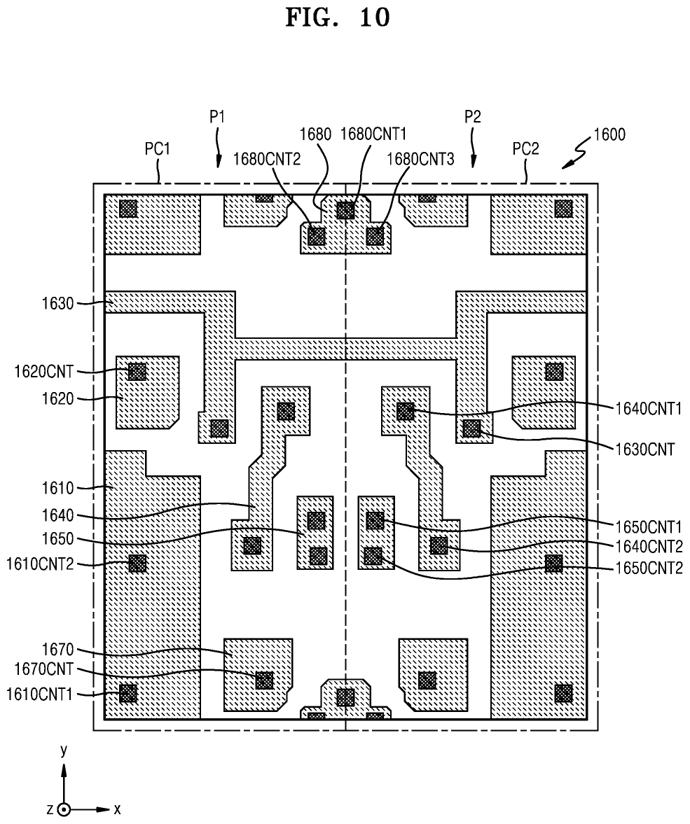

The first initialization voltage wire 1340 corresponding to the first initialization voltage line VL1 of FIG. 3 may extend in the first direction (the x-axis direction). When seen from the direction perpendicular to the substrate 100 (the z-axis direction), the first initialization voltage wire 1340 may be spaced apart from the third gate wire 1310. The first initialization voltage Vint1 may be applied to the pixels via the first initialization voltage wire 1340. The first initialization voltage wire 1340 may at least partially overlap the second semiconductor layer 1400 that will be described below and may be configured to transmit the first initialization voltage Vint1 to the second semiconductor layer 1400. The first initialization voltage wire 1340 may be electrically connected to the second semiconductor layer 1400 via contact holes 1680CNT1, 1680CNT2, and 1680CNT3 that will be described below with reference to FIG. 10.

The second conductive layer 1300 may include a metal, an alloy, conductive metal oxide, a transparent conductive material, etc. For example, the second conductive layer 1300 may include Ag, an alloy including silver, Mo, an alloy including molybdenum, Al, an alloy include aluminum, AlN, W, WN, Cu, Ni, Cr, CrN, Ti, Ta, Pt, Sc, ITO, IZO, etc. The second conductive layer 1300 may have a multi-layered structure, for example, a dual-layered structure including Mo/Al or a triple-layered structure including Mo/Al/Mo.

A first interlayer insulating layer 117 (see FIG. 12) covers the second conductive layer 1300 and may be on the second gate insulating layer 115. The first interlayer insulating layer 117 may include an insulating material. For example, the first interlayer insulating layer 117 may include silicon oxide, silicon nitride, silicon oxynitride, aluminum oxide, etc.

The second semiconductor layer 1400 as illustrated in FIG. 8 may be on the first interlayer insulating layer 117. As described above, the second semiconductor layer 1400 may include an oxide semiconductor. The second semiconductor layer 1400 may be on a different layer from the first semiconductor layer 1100, and when seen from the direction perpendicular to the substrate 100 (the z-axis direction), the second semiconductor layer 1400 may not overlap the first semiconductor layer 1100.

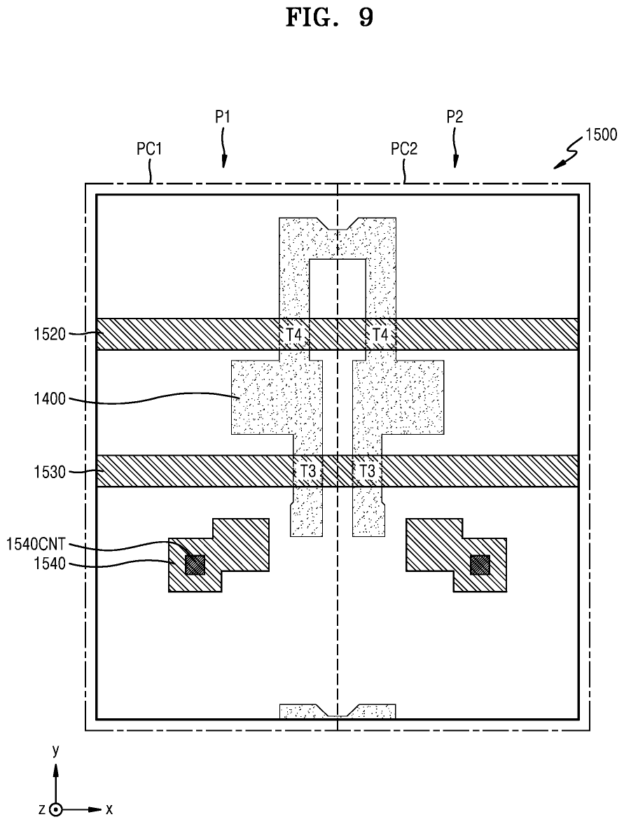

A third gate insulating layer 118 (see FIG. 12) covers the second semiconductor layer 1400 and may be on the first interlayer insulating layer 117. The third gate insulating layer 118 may include an insulating material. As necessary, the third gate insulating layer 118 may be only on a portion of the second semiconductor layer 1400 and may not be on the first interlayer insulating layer 117. In this case, the third gate insulating layer 118 may have the same pattern as a third gate layer 1500 to be described below with reference to FIG. 9. That is, when seen from the direction perpendicular to the substrate 100 (the z-axis direction), the third gate insulating layer 118 may completely or nearly completely overlap the third gate layer 1500. This is because the third gate insulating layer 118 and the third gate layer 1500 are simultaneously patterned. Therefore, in the second semiconductor layer 1400, source and drain regions may not be covered by the third gate insulating layer 118, except for channel regions overlapping the third gate layer 1500. The source and drain regions may be in direct contact with a second interlayer insulating layer 119. The third gate insulating layer 118 may include silicon oxide, silicon nitride, silicon oxynitride, aluminum oxide, etc.

The third gate layer 1500 as illustrated in FIG. 9 may be on the third gate insulating layer 118. The third gate layer 1500 may include a fifth gate wire 1520, a sixth gate wire 1530, and an intermediate electrode 1540.

The fifth gate wire 1520 may extend in the first direction (the x-axis direction). When seen from the direction perpendicular to the substrate 100 (the z-axis direction), the fifth gate wire 1520 may overlap the third gate wire 1310. In the fifth gate wire 1520, a portion overlapping the second semiconductor layer 1400 may include a first initialization upper gate electrode of the first initialization transistor T4. In the second semiconductor layer 1400, a portion overlapping the fifth gate wire 1520 and a peripheral portion may be referred to as a first initialization semiconductor layer. The fifth gate wire 1520 may be electrically connected to the third gate wire 1310. For example, the fifth gate wire 1520 may be electrically connected to the third gate wire 1310 via a contact hole defined in an insulating layer between the fifth gate wire 1520 and the third gate wire 1310. The contact hole may be in the display area DA or in the peripheral area PA. Accordingly, the fifth gate wire 1520 may correspond to the previous scan line SLp of FIG. 3, along with the third gate wire 1310. The previous scan signal Sn−1 may be applied to the pixels via the fifth gate wire 1520 and/or the third gate wire 1310.

The sixth gate wire 1530 may extend in the first direction (the x-axis direction). When seen from the direction perpendicular to the substrate 100 (the z-axis direction), the sixth gate wire 1530 may overlap the fourth gate wire 1320. In the sixth gate wire 1530, a portion overlapping the second semiconductor layer 1400 may include a compensation upper gate electrode of the compensation transistor T3. The sixth gate wire 1530 may be electrically connected to the fourth gate wire 1320. For example, the sixth gate wire 1530 may be electrically connected to the fourth gate wire 1320 via a contact hole defined in an insulating layer between the sixth gate wire 1530 and the fourth gate wire 1320. The contact hole may be in the display area DA or in the peripheral area PA. Accordingly, the sixth gate wire 1530 may correspond to the second scan line SL2 of FIG. 6, along with the fourth gate wire 1320. Accordingly, the second scan signal Sn′ may be applied to the pixels via the sixth gate wire 1530 and/or the fourth gate wire 1320.

The intermediate electrode 1540 may be electrically connected to the first gate electrode 1220, for example, the driving gate electrode, via a contact hole 1540CNT passing through an opening 1330-OP of the upper capacitor electrode 1330. The intermediate electrode 1540 may be configured to transmit the first initialization voltage Vint1 transmitted via the first initialization transistor T4 to the first gate electrode 1220.

The third gate layer 1500 may include metal, an alloy, conductive metal oxide, a transparent conductive material, etc. For example, the third gate layer 1500 may include Ag, an alloy including silver, Mo, an alloy including molybdenum, Al, an alloy include aluminum (Al), AlN, W, WN, Cu, Ni, Cr, CrN, Ti, Ta, Pt, Sc, ITO, IZO, etc. The third gate layer 1500 may have a multi-layered structure, for example, a dual-layered structure including Mo/A1 or a triple-layered structure including Mo/Al/Mo.

The second interlayer insulating layer 119 (see FIG. 12) may at least partially cover the third gate layer 1500 of FIG. 9. The second interlayer insulating layer 119 may include an insulating material. For example, the second interlayer insulating layer 119 may include silicon oxide, silicon nitride, silicon oxynitride, aluminum oxide, etc.

A first connection electrode layer 1600 as illustrated in FIG. 10 may be on the second interlayer insulating layer 119. The first connection electrode layer 1600 may include a first connection electrode 1620, a second connection electrode 1610, a second initialization voltage wire 1630, a third connection electrode 1670, a fourth connection electrode 1640, a fifth connection electrode 1650, and a sixth connection electrode 1680.

The first connection electrode 1620 may be electrically connected to the first semiconductor layer 1100 via a contact hole 1620CNT. The data signal Dm from the data wire 1710 that will be described below with reference to FIG. 11 may be transmitted to the first semiconductor layer 1100 via the first connection electrode 1620 and then may be applied to the switching transistor T2.

The second initialization voltage wire 1630 may extend in the first direction (the x-axis direction). The second initialization voltage wire 1630 corresponding to the second initialization voltage line VL2 of FIG. 6 may be configured to apply the second initialization voltage Vint2 to the pixels. The second initialization voltage wire 1630 is electrically connected to the first semiconductor layer 1100 via a contact hole 1630CNT, and the second initialization voltage Vint2 may be transmitted to the first semiconductor layer 1100 and applied to the second initialization transistor T7.

The second connection electrode 1610 may have a relatively isolated shape in a second direction (a y-axis direction). The driving voltage ELVDD from the driving voltage wire 1730 to be described below with reference to FIG. 11 is transmitted to the second connection electrode 1610. The second connection electrode 1610 electrically connected to the first semiconductor layer 1100 via a contact hole 1610CNT1 may be configured to transmit the driving voltage ELVDD to the first semiconductor layer 1100, specifically, to the operation control transistor T5. Also, the second connection electrode 1610 electrically connected to the upper capacitor electrode 1330 (i.e., the second capacitor electrode CE2 of FIG. 3) via a contact hole 1610CNT2, which may be referred to as an additional contact hole, may be configured to transmit the driving voltage ELVDD to the upper capacitor electrode 1330.

The third connection electrode 1670 may be electrically connected to the first semiconductor layer 1100 via a contact hole 1670CNT. The third connection electrode 1670 may be configured to transmit the second initialization voltage Vint2 or the driving current from the first semiconductor layer 1100 to the organic light-emitting diode OLED.

The fourth connection electrode 1640 may be configured to electrically connect the second semiconductor layer 1400 to the intermediate electrode 1540 via contact holes 1640CNT1 and 1640CNT2 defined in one side and the other side thereof. The intermediate electrode 1540 is electrically connected to the first gate electrode 1220, for example, the driving gate electrode, and thus, the fourth connection electrode 1640 may be configured to electrically connect the first initialization semiconductor layer, which is a portion of the second semiconductor layer 1400, to the driving gate electrode. The first initialization voltage Vint1 may be transmitted to the first gate electrode 1220, which is the driving gate electrode, via the second semiconductor layer 1400, the fourth connection electrode 1640, and the intermediate electrode 1540.

The fifth connection electrode 1650 may be configured to electrically connect the second semiconductor layer 1400 to the first semiconductor layer 1100 via contact holes 1650CNT1 and 1650CNT2 defined in one side and the other side thereof. That is, the fifth connection electrode 1650 may be configured to electrically connect the compensation transistor T3 to the driving transistor T1.

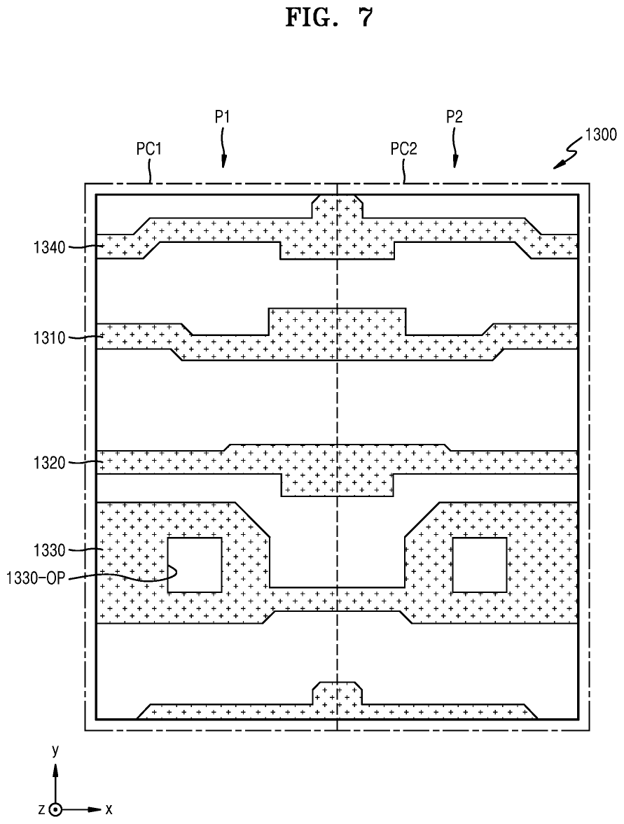

The sixth connection electrode 1680 may be electrically connected to the second semiconductor layer 1400 via the contact holes 1680CNT2 and 1680CNT3. In addition, the sixth connection electrode 1680 may be electrically connected to the first initialization voltage wire 1340 of FIG. 7 via the contact hole 1680CNT1. Accordingly, the sixth connection electrode 1680 may be configured to transmit the first initialization voltage Vint1 from the first initialization voltage wire 1340 to the first initialization transistor T4.

The first connection electrode layer 1600 may include metal, an alloy, conductive metal oxide, a transparent conductive material, etc. For example, the first connection electrode layer 1600 may include Ag, an alloy including silver, Mo, an alloy including molybdenum, Al, an alloy include aluminum, AlN, W, WN, Cu, Ni, Cr, CrN, Ti, Ta, Pt, Sc, ITO, IZO, etc. The first connection electrode layer 1600 may have a multi-layered structure, for, example, a dual-layered structure including Ti/Al or a triple-layered structure including Ti/Al/Ti.

A first planarization layer 121 covers the first connection electrode layer 1600 and may be on the second interlayer insulating layer 119. The first planarization layer 121 may include an organic insulating material. For example, the first planarization layer 121 may include photoresist, benzocyclobutene (BCB), polyimide, hexamethyldisiloxane (HMDSO), polymethylmethacrylate (PMMA), polystyrene (PS), polymer derivatives having phenol groups, acrylic polymer, imide-based polymer, aryl ether-based polymer, amide-based polymer, fluoride-based polymer, p-xylene-based polymer, vinyl alcohol-based polymer, or a mixture thereof.

A second connection electrode layer 1700 as illustrated in FIG. 11 may be on the first planarization layer 121. The second connection electrode layer 1700 may include the data wire 1710, the driving voltage wire 1730, and an upper connection electrode 1740.

The data wire 1710 may extend in the second direction (the y-axis direction). The data wire 1710 may correspond to the data line DL of FIG. 3. The data wire 1710 is electrically connected to the first connection electrode 1620 via a contact hole 1710CNT, and the data signal Dm from the data wire 1710 may be transmitted to the first semiconductor layer 1100 via the first connection electrode 1620 and then may be applied to the switching transistor T2.

The driving voltage wire 1730 may extend in the second direction (the y-axis direction). The driving voltage wire 1730 may correspond to the driving voltage line PL of FIG. 3. The driving voltage wire 1730 may be configured to apply the driving voltage ELVDD to the pixels. The driving voltage wire 1730 is electrically connected to the second connection electrode 1610 via a contact hole 1730CNT, and as described above, the driving voltage ELVDD may be transmitted to the operation control transistor T5 and the upper capacitor electrode 1330. The driving voltage wire 1730 of the first pixel circuit PCI and the driving voltage wire 1730 of the adjacent second pixel circuit PC2 may be integrally formed as a single body.

The upper connection electrode 1740 is electrically connected to the third connection electrode 1670 via a contact hole 1740CNT1. In addition, the upper connection electrode 1740 is connected to a pixel electrode 210 (see FIG. 12) disposed over the upper connection electrode 1740, via a contact hole 1740CNT2 defined in an insulating layer interposed between the upper connection electrode 1740 and the pixel electrode 210. Accordingly, the second initialization voltage Vint2 or the driving current from the first semiconductor layer 1100 may be transmitted to the first electrode (pixel electrode) of the organic light-emitting diode OLED via the third connection electrode 1670 and the upper connection electrode 1740.

The second connection electrode layer 1700 may include metal, an alloy, conductive metal oxide, a transparent conductive material, etc. For example, the second connection electrode layer 1700 may include Ag, an alloy including silver, Mo, an alloy including molybdenum, Al, an alloy include aluminum, AN, W, WN, Cu, Ni, Cr, CrN, Ti, Ta, Pt, Sc, ITO, IZO, etc. The second connection electrode layer 1700 may have a multi-layered structure, for example, a dual-layered structure including Ti/Al or a triple-layered structure including Ti/Al/Ti.

A second planarization layer 123 (see FIG. 12) covers the second connection electrode layer 1700 and may be on the first planarization layer 121. The second planarization layer 123 may include an organic insulating material. For example, the second planarization layer 123 may include photoresist, BCB, polyimide, HMDSO, PMMA, PS, polymer derivatives having phenol groups, acrylic polymer, imide-based polymer, aryl ether-based polymer, amide-based polymer, fluoride-based polymer, p-xylene-based polymer, vinyl alcohol-based polymer, or a mixture thereof.

The organic light-emitting diode OLED may be on the second planarization layer 123. The organic light-emitting diode OLED may include the pixel electrode 210, an intermediate layer 220 including an emission layer, and the opposite electrode 230.

The pixel electrode 210 may include a (semi-) transmissive electrode or a reflective electrode. For example, the pixel electrode 210 may include a reflective layer including Ag, magnesium (Mg), Al, Pt, palladium (Pd), gold (Au), Ni, neodymium (Nd), iridium (Ir), Cr, and a compound thereof, and a transparent or semi-transparent electrode layer on the reflective layer. The transparent or semi-transparent electrode layer may include at least one selected from the group consisting of ITO, IZO, zinc oxide (ZnO), indium oxide (In₂O₃), indium gallium oxide (IGO), and aluminum zinc oxide (AZO). For example, the pixel electrode 210 may have a triple-layered structure including ITO/Ag/ITO.

A pixel-defining layer 125 may be on the second planarization layer 123. The pixel-defining layer 125 may prevent arcs from occurring at an edge of the pixel electrode 210 by increasing a distance between the edge of the pixel electrode 210 and the opposite electrode 230 above pixel electrode 210. The pixel-defining layer 125 may include at least one organic insulating material selected from the group consisting of polyimide, polyamide, acrylic resin, benzocyclobutene, and phenol resin and may be formed by spin coating or the like.

At least a portion of the intermediate layer 220 in the organic light-emitting diode OLED may be in an opening OP defined in the pixel-defining layer 125. An emission area EA of the organic light-emitting diode OLED may be defined by the opening OP.

The intermediate layer 220 may include the emission layer. The emission layer may include an organic material including a fluorescent or phosphorescent material emitting red light, green light, blue light, or white light. The emission layer may include a low-molecular weight organic material or a polymer organic material, and functional layers such as a hole transport layer (HTL), a hole injection layer (HIL), an electron transport layer (ETL), and an electron injection layer (EIL) may be selectively arranged under and above the emission layer.

The emission layer may be patterned to correspond to each pixel electrode 210. Other layers than the emission layer included in the intermediate layer 220 may be variously modified, for example, may be integrally formed as a single body over a plurality of pixel electrodes 210.

The opposite electrode 230 may include a transmissive electrode or a reflective electrode. For example, the opposite electrode 230 may be a transparent or a semi-transparent electrode and may include a metal thin film including lithium (Li), calcium (Ca), Al, Ag, Mg, and a compound thereof having a small work function. Also, the opposite electrode 230 may further include a transparent conductive oxide (TCO) layer such as ITO, IZO, ZnO, In₂O₃, etc. on the metal thin film. The opposite electrode 230 is integrally formed as a single body over the entire surface of the display area DA and may be on the intermediate layer 220 and the pixel-defining layer 125.

As described above with reference to FIG. 10, the first connection electrode 1620 is connected to the first semiconductor layer 1100 via the contact hole 1620CNT of the first connection electrode 1620, the second connection electrode 1610 is connected to the first semiconductor layer 1100 via the contact hole 1610CNT1 of the second connection electrode 1610, and the third connection electrode 1670 is connected to the first semiconductor layer 1100 via the contact hole 1670CNT of the third connection electrode 1670. In addition, the second initialization voltage wire 1630 is connected to the first semiconductor layer 1100 via the contact hole 1630CNT. Therefore, the contact holes may pass through the first gate insulating layer 113, the etch stop layer 114, the second gate insulating layer 115, the first interlayer insulating layer 117, the third gate insulating layer 118, and the second interlayer insulating layer 119. Because each of the contact holes needs to pass through many insulating layers, when the contact holes are formed after the second interlayer insulating layer 119 is formed in the manufacturing process, it may not be easy to accurately adjust the depth of each of the contact holes. When each of the contact holes does not reach the first semiconductor layer 1100, a defect of the display apparatus may occur, and when any one of the contact holes penetrates the first semiconductor layer 1100, a defect of the display apparatus may occur.

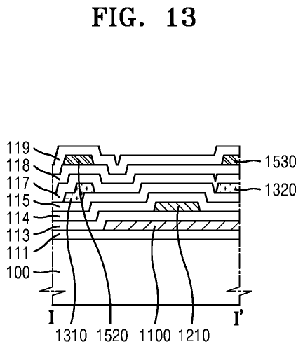

FIGS. 13 to 16 are schematic cross-sectional views illustrating operations in a method of manufacturing the display apparatus of FIG. 1. As illustrated in FIG. 13, the buffer layer 111, the first gate insulating layer 113, the etch stop layer 114, the second gate insulating layer 115, the first interlayer insulating layer 117, the third gate insulating layer 118, and the second interlayer insulating layer 119 are formed. For reference, each of the buffer layer 111, the first gate insulating layer 113, the etch stop layer 114, the second gate insulating layer 115, the first interlayer insulating layer 117, the third gate insulating layer 118, and the second interlayer insulating layer 119 may be formed by using chemical vapor deposition (CVD).

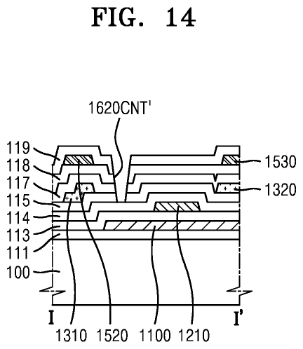

Then, as illustrated in FIG. 14, a temporary contact hole 1620CNT′ is formed in the second gate insulating layer 115, the first interlayer insulating layer 117, the third gate insulating layer 118, and the second interlayer insulating layer 119. The temporary contact hole 1620CNT′ exposes a portion of the upper surface of the etch stop layer 114.

Because the second gate insulating layer 115, the first interlayer insulating layer 117, the third gate insulating layer 118, and the second interlayer insulating layer 119 include an inorganic insulating material such as silicon oxide, silicon nitride, silicon oxynitride, or aluminum oxide, the temporary contact hole 1620CNT′ may be formed by etching a layer including the inorganic insulating material. In detail, after a photoresist layer is formed on the second interlayer insulating layer 119 and an opening is formed in a predetermined portion of the photoresist layer, the temporary contact hole 1620CNT′ may be formed by etching predetermined portions of the second gate insulating layer 115, the first interlayer insulating layer 117, the third gate insulating layer 118, and the second interlayer insulating layer 119 by using a gas including fluorine such as CHF₃, C₄F₈, C₂HF₅, CH₂F₂, etc. In this case, the etch stop layer 114, which is an amorphous carbon layer, is resistant to fluorine, and thus is etched slightly, if at all, in the process of forming the temporary contact hole 1620CNT′. Therefore, in the process of forming the temporary contact hole 1620CNT′, the temporary contact hole 1620CNT′ may be smoothly formed without considering problems such as over-etching or the like.

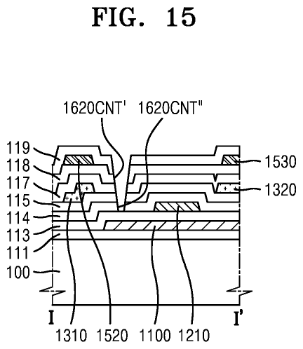

After the temporary contact hole 1620CNT′ is formed, an additional temporary contact hole 1620CNT″ is formed as illustrated in FIG. 15 by removing a portion of the etch stop layer 114 exposed by the temporary contact hole 1620CNT′. The additional temporary contact hole 1620CNT″ defined in the etch stop layer 114 is integrally formed as a single body with the temporary contact hole 1620CNT′ defined thereon. An oxygen plasma treatment method may be used to form the additional temporary contact hole 1620CNT″ in the etch stop layer 114. As described above, because the etch stop layer 114 is an amorphous carbon layer, the amorphous carbon layer may be plasma ashed by oxygen. Therefore, when oxygen plasma treatment is performed in a state in which the temporary contact hole 1620CNT′ is formed, the additional temporary contact hole 1620CNT″ is formed by removing the portion of the etch stop layer 114 exposed by the temporary contact hole 1620CNT′.

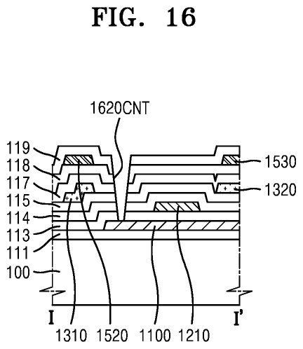

Then, as illustrated in FIG. 16, the contact hole 1620CNT may be formed in the first gate insulating layer 113, the etch stop layer 114, the second gate insulating layer 115, the first interlayer insulating layer 117, the third gate insulating layer 118, and the second interlayer insulating layer 119 by removing a portion of the first gate insulating layer 113 exposed by the additional temporary contact hole 1620CNT″. The removal of the portion of the first gate insulating layer 113 exposed by the additional temporary contact hole 1620CNT″ may be performed in the same manner as the formation of the temporary contact hole 1620CNT′. In this case, because only the portion of the first gate insulating layer 113 is removed, not several insulating layers, the depth thereof may be accurately controlled, thereby minimizing or preventing problems such as damage to the first semiconductor layer 1100 or over-etching of the first semiconductor layer 1100.

As illustrated in FIG. 16, after the contact hole 1620CNT is formed, the first connection electrode layer 1600 including the first connection electrode 1620 in contact with the first semiconductor layer 1100 via the contact hole 1620CNT is formed. The process of forming the contact hole 1620CNT described above may be applied to the process of forming the contact hole 1610CNT1, the contact hole 1670CNT, and the contact hole 1630CNT. In the manufacturing process, the contact hole 1620CNT, the contact hole 1610CNT1, the contact hole 1670CNT, and the contact hole 1630CNT may be simultaneously formed through the same process.

After the first connection electrode layer 1600 is formed, the first planarization layer 121, which is an organic insulating layer, is formed to cover the first connection electrode layer 1600, and the contact hole 1710CNT, which exposes at least a portion of the first connection electrode 1620, is formed in the first planarization layer 121. In addition, the second connection electrode layer 1700 including the data wire 1710 connected to the first connection electrode 1620 via the contact hole 1710CNT defined in the first planarization layer 121 is formed on the first planarization layer 121.

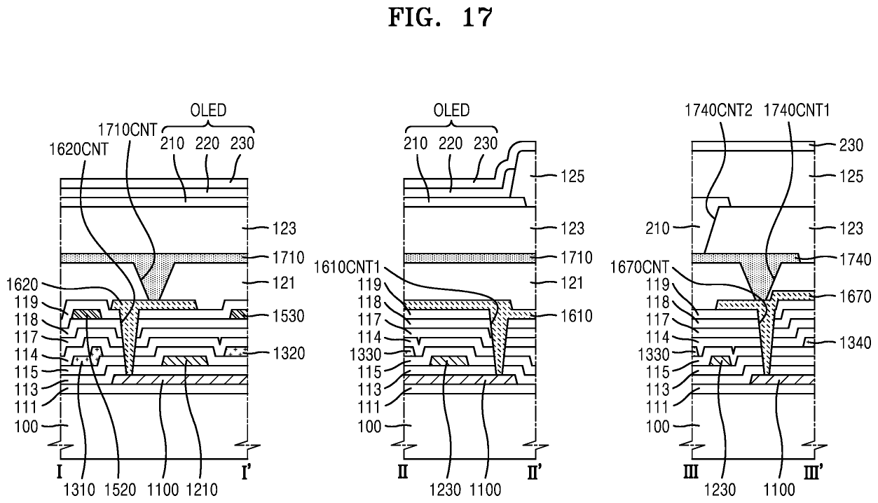

FIG. 17 is a schematic cross-sectional view of cross-sections of portions of the display apparatus according to an embodiment. The display apparatus according to the embodiment is different from the display apparatus according to the embodiment described above with reference to FIGS. 12 to 16 in terms of the location of the etch stop layer 114. In detail, in the display apparatus according to the embodiment, the etch stop layer 114 covers the second conductive layer 1300, is on the second gate insulating layer 115, and the first interlayer insulating layer 117 covers the etch stop layer 114.

In the case of the display apparatus according to the embodiment, a temporary contact hole is formed in the first interlayer insulating layer 117, the third gate insulating layer 118, and the second interlayer insulating layer 119 during the manufacturing process. The temporary contact hole exposes a portion of the upper surface of the etch stop layer 114. Then, an additional temporary contact hole is formed in the etch stop layer 114 by removing the portion of the etch stop layer 114 exposed by the temporary contact hole. The additional temporary contact hole defined in the etch stop layer 114 is integrally formed as a single body with the temporary contact hole thereon. Then, as illustrated in FIG. 17, the contact hole 1620CNT, the contact hole 1610CNT1, and the contact hole 1670CNT may be formed in the first gate insulating layer 113, the second gate insulating layer 115, the etch stop layer 114, the first interlayer insulating layer 117, the third gate insulating layer 118, and the second interlayer insulating layer 119 by removing portions of the first gate insulating layer 113 and the second gate insulating layer 115 exposed by the additional temporary contact holes. The removal of the portions of the first gate insulating layer 113 and the second gate insulating layer 115 exposed by the additional temporary contact holes may be performed by the same method as the formation of the temporary contact holes. In this case, because the portions of the first gate insulating layer 113 and the second gate insulating layer 115, which may be referred to as a only two-layered structure, are removed, the depth thereof may be accurately controlled, thereby minimizing or preventing problems such as damage to the first semiconductor layer 1100 or over-etching of the first semiconductor layer 1100. A subsequent process is the same as the manufacturing process of the display apparatus according to the aforedescribed embodiment.

As described above, during the process of patterning an inorganic insulating layer directly under the etch stop layer 114, the etch stop layer 114 may prevent a layer under the inorganic insulating layer from being over-etched or damaged. In addition, each of removed portions of the etch stop layer 114 is used to remove a corresponding portion of the inorganic insulating layer directly under the etch stop layer 114. Accordingly, the etch stop layer 114 is patterned in the same shape as the inorganic insulating layer directly thereunder. That is, each of through-holes of the etch stop layer 114 is connected to a corresponding through-hole of the inorganic insulating layer directly under the etch stop layer 114. In addition, the number of through-holes of the etch stop layer 114 is equal to the number of through-holes of the inorganic insulating layer directly under the etch stop layer 114.

According to the one or more embodiments as described above, the display apparatus capable of preventing or minimizing defects occurring in the manufacturing process, and the method of manufacturing the same may be implemented. The scope of the disclosure is not limited to the above effects.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
a substrate;
a first semiconductor layer on the substrate;
a first gate insulating layer that covers the first semiconductor layer;
a first conductive layer provided on the first gate insulating layer, the first conductive layer including a gate wire including a switching gate electrode;
an etch stop layer that covers the first conductive layer;
a second gate insulating layer that covers the etch stop layer;
a second conductive layer provided on the second gate insulating layer, the second conductive layer including a upper capacitor electrode;
a first interlayer insulating layer that covers the second conductive layer;
a second semiconductor layer provided on the first interlayer insulating layer;
a third gate insulating layer that covers the second semiconductor layer;
a second interlayer insulating layer that covers the third gate insulating layer; and
a first connection electrode layer provided on the second interlayer insulating layer, the first connection electrode layer including a first connection electrode in contact with the first semiconductor layer via a contact hole defined in the first gate insulating layer, the etch stop layer, the second gate insulating layer, the first interlayer insulating layer, the third gate insulating layer, and the second interlayer insulating layer.

2. The display apparatus of claim 1, wherein the etch stop layer includes a material different from a material included in the first gate insulating layer, the second gate insulating layer, the first interlayer insulating layer, the third gate insulating layer, and the second interlayer insulating layer.

3. The display apparatus of claim 1, wherein the etch stop layer includes an amorphous carbon layer, and each of the first gate insulating layer, the second gate insulating layer, the first interlayer insulating layer, the third gate insulating layer, and the second interlayer insulating layer includes an inorganic material.

4. The display apparatus of claim 3, wherein each of the first gate insulating layer, the second gate insulating layer, the first interlayer insulating layer, the third gate insulating layer, and the second interlayer insulating layer includes silicon oxide, silicon nitride, or silicon oxynitride.

5. The display apparatus of claim 1, further comprising:
a first planarization layer that covers the first connection electrode layer; and
a second connection electrode layer provided on the first planarization layer, the second connection electrode layer including a data wire connected to the first connection electrode via a contact hole defined in the first planarization layer.

6. The display apparatus of claim 5, wherein the first planarization layer includes an organic insulating layer.

7. The display apparatus of claim 5, wherein the first connection electrode layer further includes a second connection electrode in contact with the first semiconductor layer via a contact hole defined in the first gate insulating layer, the etch stop layer, the second gate insulating layer, the first interlayer insulating layer, the third gate insulating layer, and the second interlayer insulating layer.

8. The display apparatus of claim 7, wherein the second connection electrode layer further includes a driving voltage wire connected to the second connection electrode via a contact hole defined in the first planarization layer.

9. The display apparatus of claim 8, wherein the second connection electrode is connected to the upper capacitor electrode via an additional contact hole defined in the first interlayer insulating layer, the third gate insulating layer, and the second interlayer insulating layer.

10. The display apparatus of claim 5, wherein the first connection electrode layer further includes a third connection electrode in contact with the first semiconductor layer via a contact hole defined in the first gate insulating layer, the etch stop layer, the second gate insulating layer, the first interlayer insulating layer, the third gate insulating layer, and the second interlayer insulating layer.

11. The display apparatus of claim 10, wherein the second connection electrode layer further includes an upper connection electrode connected to the third connection electrode via a contact hole defined in the first planarization layer.

12. The display apparatus of claim 11, further comprising:
a second planarization layer that covers the second connection electrode layer; and
a pixel electrode connected to the upper connection electrode through a contact hole defined in the second planarization layer.

13. A method of manufacturing a display apparatus, the method comprising:
forming a first semiconductor layer on a substrate;
forming a first gate insulating layer to cover the first semiconductor layer;
forming, on the first gate insulating layer, a first conductive layer including a gate wire including a switching gate electrode;
forming an etch stop layer to cover the first conductive layer;
forming a second gate insulating layer to cover the etch stop layer;
forming, on the second gate insulating layer, a second conductive layer including a upper capacitor electrode;
forming a first interlayer insulating layer to cover the second conductive layer;
forming a second semiconductor layer on the first interlayer insulating layer;
forming a third gate insulating layer to cover the second semiconductor layer;
forming a second interlayer insulating layer to cover the third gate insulating layer;
forming a first temporary contact hole in the second gate insulating layer, the first interlayer insulating layer, the third gate insulating layer, and the second interlayer insulating layer;
forming a second temporary contact hole by removing a portion of the etch stop layer exposed by the first temporary contact hole;
forming a contact hole in the first gate insulating layer, the etch stop layer, the second gate insulating layer, the first interlayer insulating layer, the third gate insulating layer, and the second interlayer insulating layer by removing a portion of the first gate insulating layer exposed by the second temporary contact hole; and
forming, on the second interlayer insulating layer, a first connection electrode layer including a first connection electrode in contact with the first semiconductor layer via the contact hole.

14. The method of claim 13, wherein the forming of the first temporary contact hole includes using a gas including fluorine, and
the forming of the second temporary contact hole includes oxygen plasma treatment.

15. The method of claim 14, wherein the removing of the portion of the first gate insulating layer exposed by the second temporary contact hole includes using a gas including fluorine.

16. The method of claim 13, wherein a material used in the forming of the etch stop layer is different from a material used in the forming of the first gate insulating layer, the forming of the second gate insulating layer, the forming of the first interlayer insulating layer, the forming of the third gate insulating layer, and the forming of the second interlayer insulating layer.

17. The method of claim 13, wherein the forming of the etch stop layer includes forming an amorphous carbon layer, and
each of the forming of the first gate insulating layer, the forming of the second gate insulating layer, the forming of the first interlayer insulating layer, the forming of the third gate insulating layer, and the forming of the second interlayer insulating layer includes forming an inorganic insulating layer.

18. The method of claim 17, wherein each of the forming of the first gate insulating layer, the forming of the second gate insulating layer, the forming of the first interlayer insulating layer, the forming of the third gate insulating layer, and the forming of the second interlayer insulating layer includes forming a layer including silicon oxide, silicon nitride or silicon oxynitride.

19. The method of claim 13, further comprising:
forming a first planarization layer to cover the first connection electrode layer;
forming, on the first planarization layer, a contact hole exposing at least a portion of the first connection electrode; and
forming, on the first planarization layer, a second connection electrode layer including a data wire connected to the first connection electrode via the contact hole defined in the first planarization layer.

20. The method of claim 19, wherein the forming of the first planarization layer includes forming an organic insulating layer.
